(19) United States
(12) Patent Application Publication
(10) Pub. No.: US 2011/0239749 A1
(43) Pub. Date: Oct. 6, 2011

(54) CYLINDER HEAD COMPRESSION SENSOR GASKET ASSEMBLY, METHOD OF CONSTRUCTION THEREOF AND METHOD OF SERVICING A PRESSURE SENSOR ASSEMBLY IN A CYLINDER HEAD COMPRESSION SENSOR GASKET ASSEMBLY

(76) Inventors: David M. Toth, Brighton, MI (US); Marek Wlodarczyk, Bloomfield Hills, MI (US); Bhawani Tripathy, Ann Arbor, MI (US); Jonathan Youngman, Ann Arbor, MI (US); James Stout, Pinckney, MI (US)

(21) Appl. No.: 13/076,965

(22) Filed: Mar. 31, 2011

Related U.S. Application Data
(60) Provisional application No. 61/319,295, filed on Mar. 31, 2010.
(60) Provisional application No. 61/421,790, filed on Dec. 10, 2010.

(51) Int. Cl. G01M 15/08; H05K 13/00; B23P 6/00

(52) U.S. Cl. 73/114.18; 29/592.1; 29/402.08

(57) ABSTRACT

A cylinder head compression sensor gasket assembly includes a gasket body having a sealing portion configured to be clamped between an engine block and a cylinder head. The sealing portion has a plurality of through openings configured to register with separate cylinder bore in the engine block wherein the sealing portion establishes a gas-tight seal about the through passages. A plurality of pressure sensor assemblies are attached in sealed engagement with the gasket body with at least one of the pressure sensor assemblies being configured to sense pressure within a separate one of the through openings. An electrical connector is supported on the gasket body radially outwardly from the sealing portion. The electrical connector is configured in electrical communication with each of the pressure sensor assemblies. Accordingly, the electrical connector is accessible without having to disassemble the gasket body from being clamped between the cylinder head and the engine block.

### CROSS-REFERENCE TO RELATED APPLICATION

This application claims the benefit of U.S. Provisional Application Ser. No. 61/319,295, filed Mar. 31, 2010, and also the benefit of U.S. Provisional Application Ser. No. 61/421,790, filed Dec. 10, 2010, which are both incorporated herein by reference in their entirety.

### BACKGROUND OF THE INVENTION

1. Technical Field

This invention relates generally to internal combustion engines, and more particularly to compression gaskets for forming a seal about a chamber within an internal combustion engine.

2. Related Art

Internal combustion engines have chambers in which high pressures are generated. Generally, a pair of members mate with one another to form the chamber or chambers, such as a cylinder head and engine block, for example, forming a plurality of cylinder chambers with a gasket being received between the members to provide a gas/fluid tight seal about the chambers. In addition to the gasket, it is known to provide separate pressure sensors to indicate the respective pressures within the chambers. Having separate gasket and sensor components typically comes at an increased cost, both in manufacture and assembly.

Some attempts have been made to provide a single component gasket and compression sensor assembly. However, these attempts have not been successful due to an increased cost associated therewith, particularly during service. The known gasket/sensor assemblies must be replaced in their entirety during service, thereby leading to the increased cost of having to replace both the gasket and the sensor. Accordingly, what is needed is a gasket and sensor assembly that can provide a reliable seal between mating members, including between the gasket and the individual pressure sensors, provide an accurate indication of the pressure within the combustion chamber, provide a gasket with its thickness minimally increased due to pressure sensor integration, provide an ability to route the sensor about passages extending between the cylinder head and the engine block, have separately replaceable components in service, allow replacement of electronics without having to disassemble the cylinder head from the engine block, and be provided in an economical fashion, both in manufacture and in use.

### SUMMARY OF THE INVENTION

A cylinder head compression sensor gasket assembly constructed in accordance with one aspect of the invention includes a gasket body having a sealing portion configured to be clamped between an engine block and a cylinder head. The sealing portion has a plurality of through openings extending therethrough. Each of the through openings is configured to register with separate cylinder bore in the engine block wherein the sealing portion establishes a gas-tight seal about the through passages. A plurality of pressure sensor assemblies are attached in sealed engagement with the gasket body with at least one of the pressure sensor assemblies being configured to sense pressure within a separate one of the through openings. An electrical connector is supported on the gasket body radially outwardly from the sealing portion. The electrical connector is configured in electrical communication with each of the pressure sensor assemblies. Accordingly, the electrical connector is accessible without having to disassemble the gasket body from being clamped between the cylinder head and the engine block.

A compression sensor gasket assembly constructed in accordance with another aspect of the invention includes a gasket body assembly having a gasket body with a passage extending into a through opening configured to register with a cylinder bore of an internal combustion engine and a pressure sensor assembly received in the passage to indicate the pressure within the cylinder bore. The pressure sensor assembly is releasably attached in sealed engagement to the gasket body and is at least partially removable from between a cylinder head and cylinder block of the engine with having to detach the cylinder head and cylinder block from one another in service.

In accordance with another aspect of the invention, a method of constructing a pressure sensor gasket body assembly for sensing pressure within a cavity of an internal combustion engine is provided. The method includes providing a substantially flat gasket body having an outer periphery and a through opening configured to register with a cylinder bore in the internal combustion engine. Further, forming a passage extending into the through passage. Then, attaching a sensor assembly in the passage with a sensor portion of the sensor assembly facing the through opening, wherein at least a portion of the sensor assembly is removable from between a cylinder head and cylinder block of the engine without having to detach the cylinder head and cylinder block from one another.

In accordance with another aspect of the invention, a method of servicing a pressure sensor assembly at least partially sandwiched between a cylinder head and cylinder block of an internal combustion engine is provided. The method includes, while leaving the cylinder head attached to the engine block, removing at least a portion of the pressure sensor assembly from between the cylinder head and the cylinder block and inserting a replacement portion of the pressure sensor assembly therebetween.

In accordance with another aspect of the invention, the sensor assembly includes a pressure sensor removably attached to the gasket body and electronics disposed in the gasket body and attached in electrical communication with the pressure sensor.

In accordance with another aspect of the invention, the pressure sensor is permanently fixed to the gasket body and at least a portion of the electronics are removable therefrom.

In accordance with another aspect of the invention, a plurality of pressure sensors are attached to the gasket body, wherein the pressure sensors are individually removable from the gasket body.

In accordance with another aspect of the invention, a PCB is attached to the gasket body and each of the pressure sensors is configured in electrical communication with the PCB.

In accordance with another aspect of the invention, the pressure sensor gasket has a single port for electrical connection to an engine control unit.

In accordance with another aspect of the invention, each of the pressure sensors is configured in electrical communication with a separate electronic source.

In accordance with another aspect of the invention, the gasket body has a portion configured to extend outwardly from the cylinder head and engine block and further includes a detachable cover removably attached to the portion to cover electronics of the pressure sensors.

### BRIEF DESCRIPTION OF THE DRAWINGS

These and other aspects, features and advantages of the invention will become more readily appreciated when considered in connection with the following detailed description of presently preferred embodiments and best mode, appended claims and accompanying drawings, in which:

FIG. 1 is a plan view of a gasket body assembly constructed in accordance with one presently preferred aspect of the invention;

FIG. 1A is plan view of the gasket body assembly of FIG. 1 shown with an electronics cover removed;

FIG. 1B is a right side view of the gasket body assembly of FIG. 1;

FIG. 1C is a left side view of the gasket body assembly of FIG. 1;

FIG. 2 is a view similar to FIG. 1A showing the cover and a pressure sensor assembly of the gasket body assembly removed from the assembly;

FIGS. 3A-3C show enlarged views of the gasket body assembly of FIG. 1;

FIG. 4 shows a cross-sectional view taken generally along the central longitudinal axis of the pressure sensor of FIG. 3B;

FIGS. 4A-4F show enlarged cross-sectional views of a pressure sensor tip region in accordance with various aspects of the invention;

FIG. 5 shows a cross-sectional mounted configuration of the pressure sensor assembly within the gasket body in accordance with one aspect of the invention;

FIG. 5A shows an enlarged portion of the encircled area 5A of FIG. 5;

FIG. 5B shows side view of the gasket body of FIG. 5 with the pressure sensor assembly removed from the gasket body;

FIG. 6 shows a perspective view of a gasket body constructed in accordance with another aspect of the invention;

FIG. 6A shows a cross-sectional view taken generally along the line 6A-6A of FIG. 6 with a pressure sensor assembly assembled to the gasket body;

FIG. 7 show an exploded view of a gasket body assembly constructed in accordance with another aspect of the invention;

FIG. 8A shows a top perspective view of a gasket body assembly constructed in accordance with another aspect of the invention;

FIG. 8B is a similar view to FIG. 8A with a an electronics cover removed from the assembly;

FIG. 8C shows a bottom perspective view of a gasket body assembly of FIG. 8A;

FIG. 9 shows a partial perspective assembled view of a gasket body assembly constructed in accordance with another aspect of the invention;

FIG. 9A shows a cross-section of the gasket body assembly of FIG. 9 illustrating a mechanism for fixing the pressure sensor assembly to the gasket body in accordance with one aspect of the invention;

FIGS. 9B-9E shown different mechanisms for fixing a pressure sensor assembly to a gasket body in accordance with other aspects of the invention;

FIG. 10 shows a schematic plan view of a gasket body assembly with the pressure sensors mounted on an exhaust side of the gasket body with the electronics located in an accessible and/or environmentally less severe area of the cylinder head gasket;

FIG. 11 shows a schematic plan view of a gasket body assembly with pressure sensor assemblies having integral electronics housed in the pressure sensor assemblies in accordance with another aspect of the invention; and

FIG. 11A shows an enlarged view of the integral electronics in the pressure sensor assembly.

### DETAILED DESCRIPTION OF PRESENTLY PREFERRED EMBODIMENTS

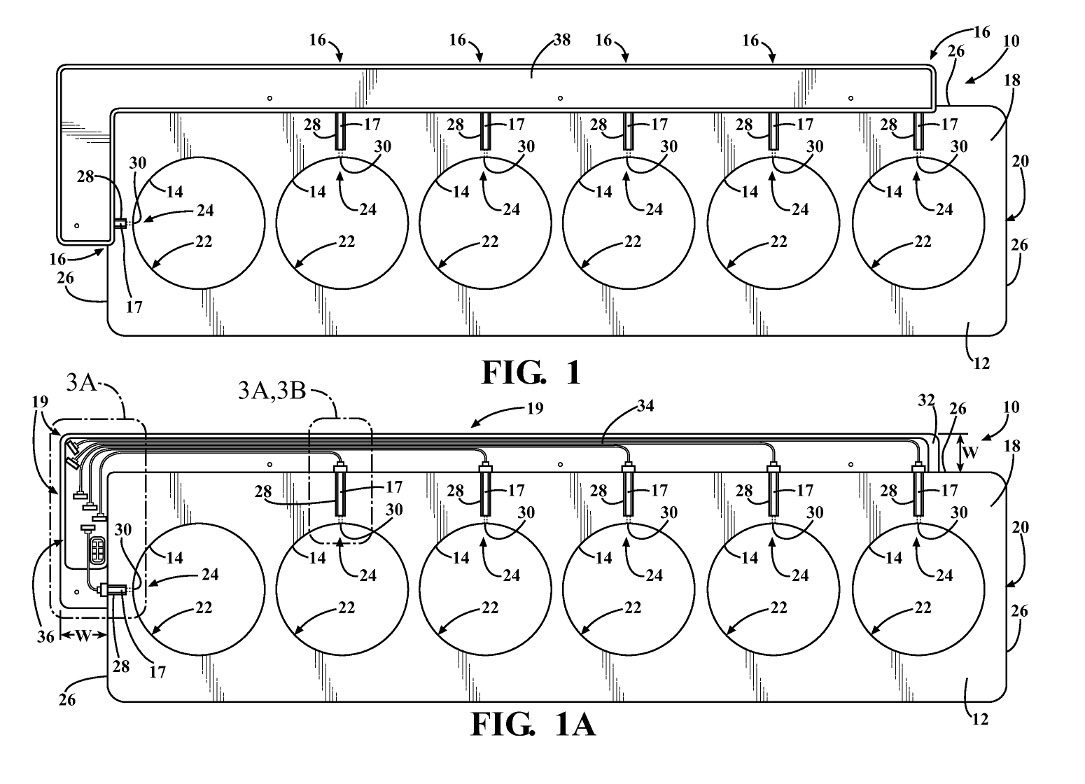

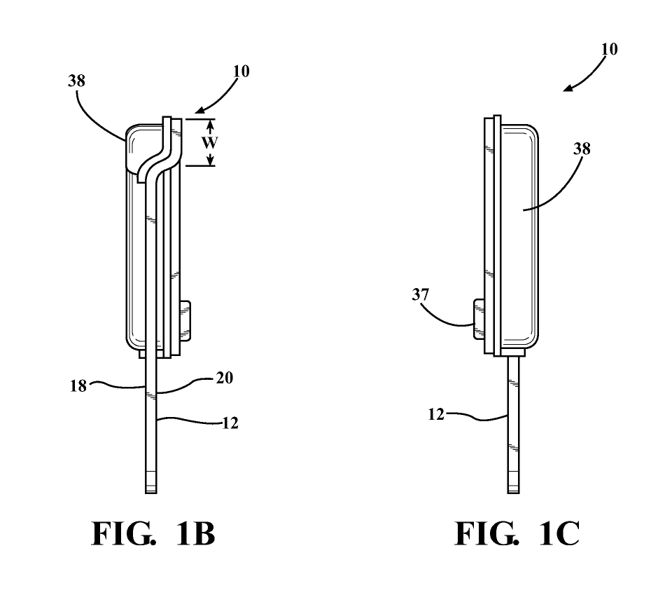

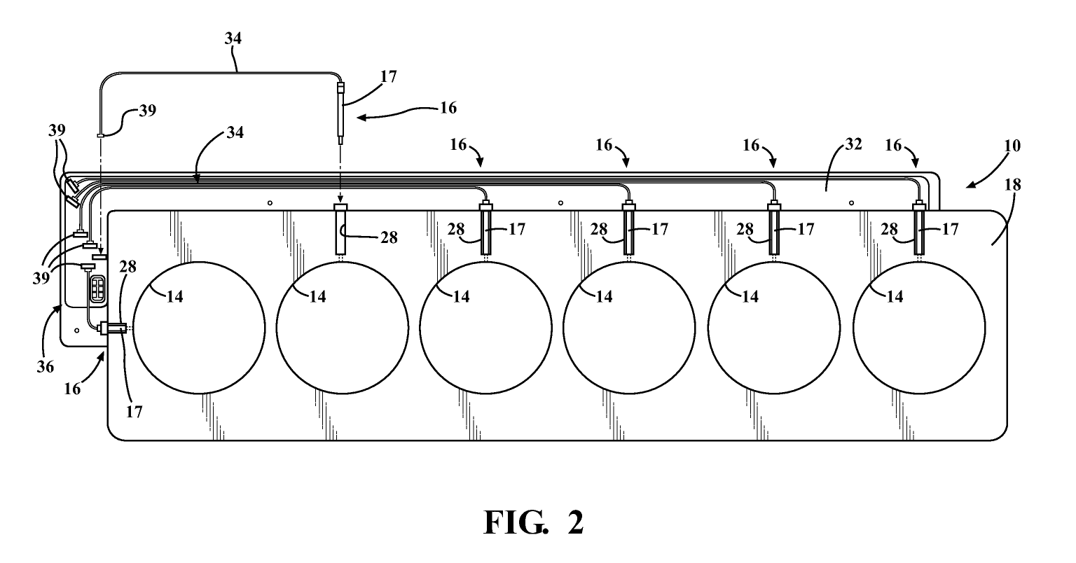

Referring in more detail to the drawings, FIG. 1 illustrates a compression sensor gasket assembly, referred to hereafter as gasket assembly 10, constructed in accordance with one presently preferred embodiment of the invention. The gasket assembly 10 has a metal distance layer, referred to hereafter as a gasket body 12, with one or more through openings, also referred to as through passages 14, for the passage of fluid or gas therethrough, such as an opening configured to register in axial alignment with a cylinder bore of an internal combustion engine (not shown), for example. The gasket assembly 10 has a pressure sensor assembly 16 at least partially releasably attached in sealed engagement with the gasket body 12. The pressure sensor assembly 16 includes a pressure sensor 17 that is configured to sense pressure within the through passage 14 and within the cylinder bore being sealed. Electronic members 19 are configured in electrical communication with the pressure sensor 17. In service, at least a portion of the pressure sensor assembly 16, whether it be the pressure sensor 17 and/or the electronic members 19, can be readily removed from the gasket body 12 without removing or otherwise unclamping the gasket body 12 from between a cylinder head and engine block, such that the desired portion of the sensor assembly 16 can be replaced in the plane of the gasket body 12, as necessary.

The gasket body 12 can be provided as a monolithic piece of material having a flat or substantially flat body, having minimal thickness extending between opposite sides that provide sealing surfaces 18, 20. The sealing surfaces 18, 20 are configured for sealed engagement directly with a cylinder head, engine block and/or with one or more functional layers fabricated from a resilient metal (not shown), such as spring steel, for example, having sealing beads, including half and/or full sealing beads, as desired. The through passages 14 have an inner surface or periphery 22 configured to register with the passage, e.g. cylinder bore in the engine block, being sealed. To facilitate attaching the pressure sensor assembly 16 to the gasket body 12 either through the inner periphery 22 or from a radially outer portion of the body 12, the gasket body 12 has a plurality of channels, also referred to as passages 24 extending from an outer periphery 26 (the outer most portion of the gasket body 12 that is sandwiched between a cylinder head and an engine block) into each through passage 14. The passages 24 can be formed as a through slots (extending completely through the thickness of the body 12); enclosed tubular passages extending between the opposite sealing surfaces 18, 20, or a combination thereof. In one preferred embodiment, which provides a minimum thickness to the gasket body 12, and thus, provides a minimum total gasket assembly thickness, the passages 24 can be formed having through slot portions 28 extending from the outer periphery 26 radially inwardly toward the through passages 14. The through slot portions 28 can be milled or otherwise cut through the sealing surfaces 18, 20. In addition, the passages 24 can be formed having an enclosed tubular portion 30. The tubular portions 30 can be formed in a drilling operation, for example, wherein the tubular portions 30 are shown as extending radially inwardly from the through slot portions 28 to the inner peripheries 22 of the through passages 14. The drilled portions 30 can be sized for a close fit, such as line-to-line, with an outer portion of the pressure sensor 17, or it can be enlarged for receipt of an adaptor sleeve, seal, heat shield, or other type of fitting, or to provide a loose fit via an annular gap extending about at least a portion of the pressure sensor assembly 16.

The gasket body 12 has a peripheral shelf 32 extending generally laterally outwardly from at least a portion of the outer periphery 26. The shelf 32 is illustrated as extending laterally outwardly from the pressure sensors 17, thereby extending substantially along the length of one of the sides of the gasket body 12. The shelf 32 is configured having a width (w, FIGS. 1A-1B) sufficient to support the electronic members 19, including wires 34, a printed circuit board 36 (PCB), wherein the PCB can be provided having a pig tail or a multi-pin type connector 37 (FIG. 1C).

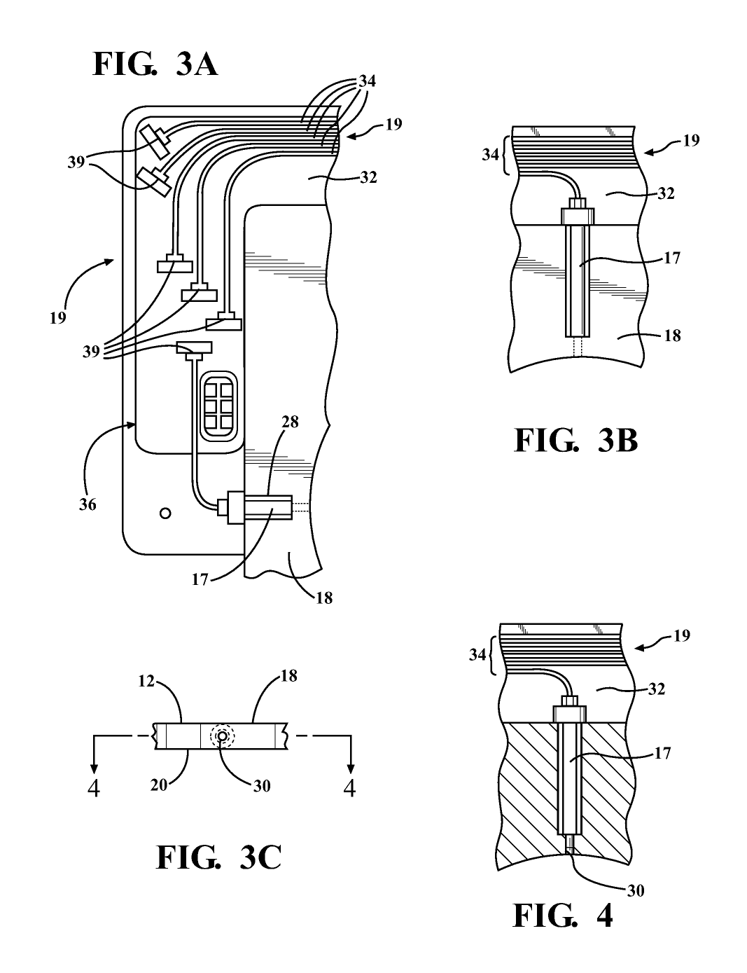

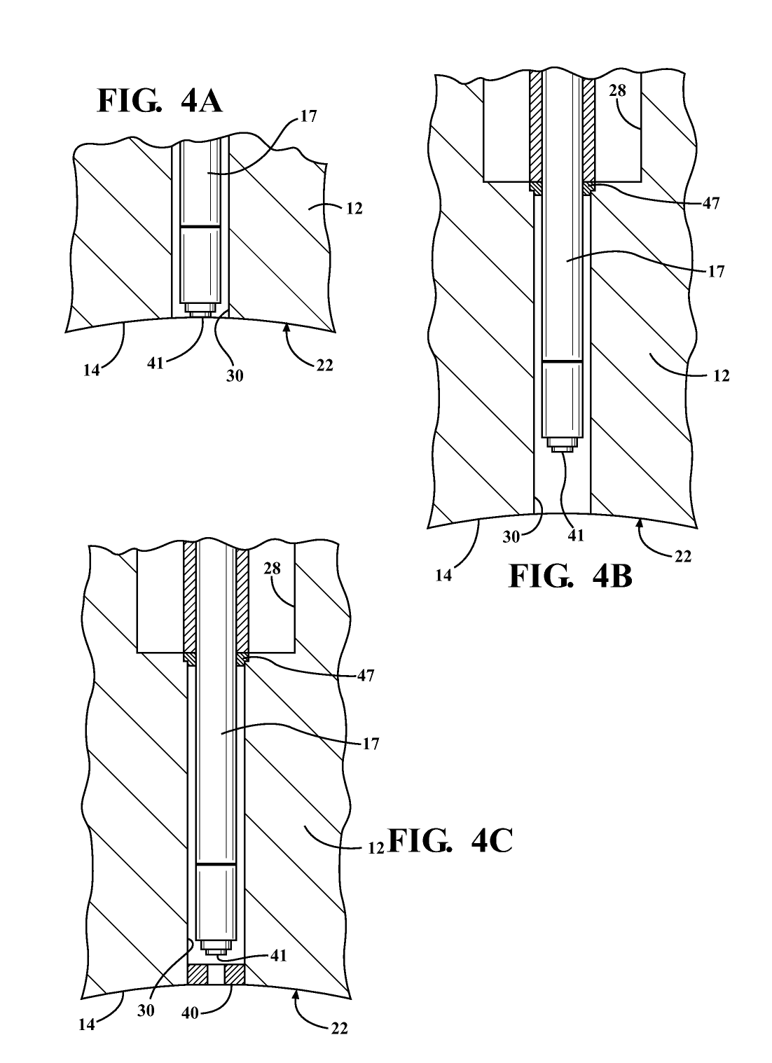

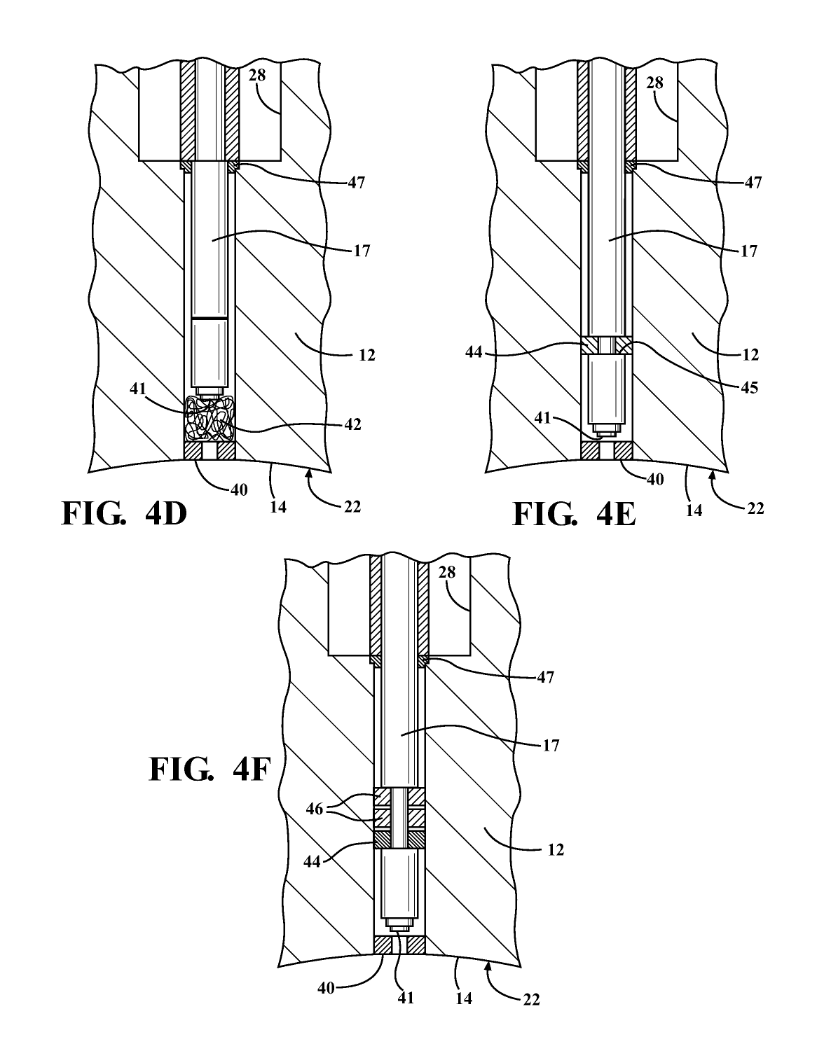

Upon routing the wires 34 of the electronic members 19 on the shelf 32 and plugging them into the PCB 36, such as via a press fit or snap-in-place plug or an otherwise insertable connector 39 (FIG. 3A) at the ends of the wires 34 (FIGS. 3 and 4A), a cover 38 is preferably disposed in sealing relation over the electronic members 19 and thus, the cover 38 provides protection to the electronic members 19 against impact, abrasion and contamination, and can be selectively removed as desired to allow ready access to the electronic members 19 and ultimately, to the pressure sensors 17. The cover 38 and electronic members 19 can be integrated into a one-piece removable assembly that plugs into the gasket body 12 to make all the necessary electrical connections for proper operation.

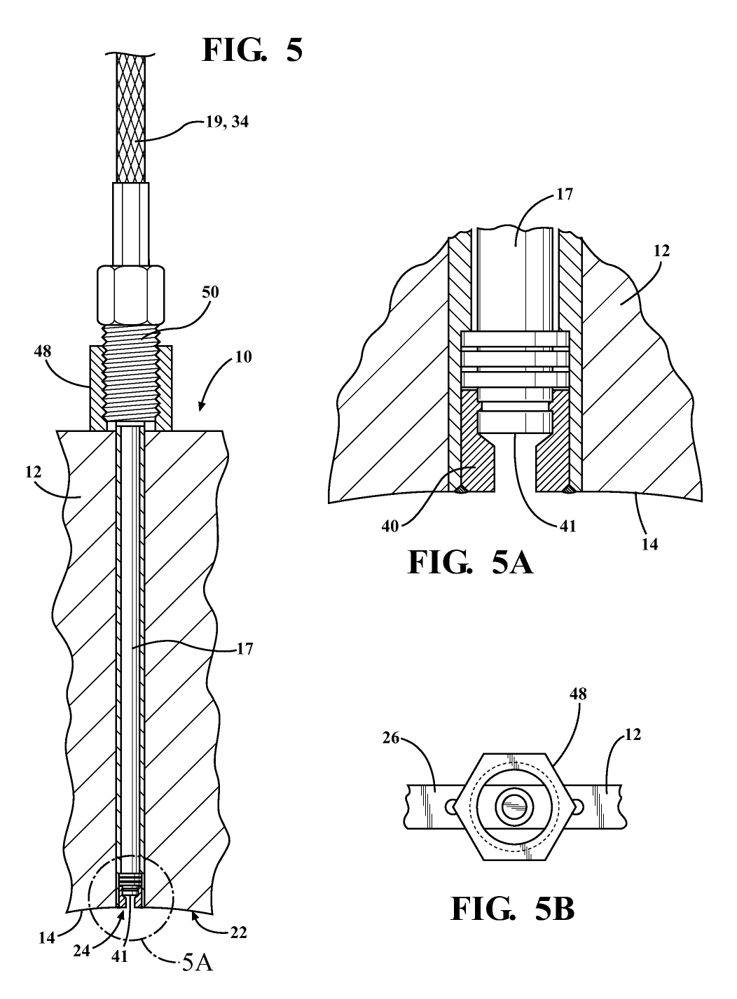

As best shown in FIGS. 4A-4F, the pressure sensors 17 have end portions and sensor tips 41 that can be configured in a variety of ways. For example, the pressure sensor tip 41 can be mounted flush or substantially flush with the inner periphery 22 (FIG. 4A); it can be recessed radially outwardly from the inner periphery 22 (FIG. 4B); it can be recessed radially outwardly from the inner periphery 22 sufficiently to accommodate an annular heat shield 40 (FIGS. 4C-4F and 5-5A); it can be recessed radially outwardly from the inner periphery 22 sufficiently to accommodate an insulative and/or heat-exchanging material, such as a wire mesh 42 between the heat shield 40 and the sensor tip 41 (FIG. 4D); in addition to the heat shield 40 an annular heat ring 44 can be disposed about the sensor body and the opening 30, such as within an annular groove 45 of the pressure sensor 17 body (FIG. 4E); and it can also have one or more O-ring seals 46 in addition to a sealing member 47 disposed radially outwardly from the heat ring 44 (FIG. 4F), wherein the sealing member 47 is shown having a reduced diameter portion sized for receipt in the tubular portion 30 and a shoulder extending to an enlarged diameter portion received in a slightly enlarged counter bore. Accordingly, the shoulder acts as a stop surface within the counter bore. The pressure sensors 17 can be provided in a precalibrated state, such that they can be installed in service and plugged into a signal conditioner. Thus, each sensor 17 does not have to be individually calibrated to a specific sensitivity value.

As shown in FIGS. 5 and 5B, to facilitate attaching the pressure sensor assembly 16 to the gasket body 12, a nut 48 can be fixed, such as via welding, to the outer periphery 26. The nut 48 is configured in axial alignment with the passage 24 and is sized for threaded attachment to a male threaded portion 50 of the pressure sensor 17 and/or an outer housing of the pressure sensor 17. Further, as shown in FIGS. 5 and 5A, to protect the sensor tip positioned adjacent the through opening 14 from excessive exposure to heat, an annular heat shield 40 can be disposed between the through opening 14 and the sensor tip 41. The heat shield 40 is shown, by way of example, as having an enlarged bore portion receiving the sensor tip 41 therein and a reduced diameter bore portion extending to or substantially to the through opening 14. The reduced diameter bore portion functions to shield the heat generated within the cylinder bore from radiating directly to the pressure sensor tip 41.

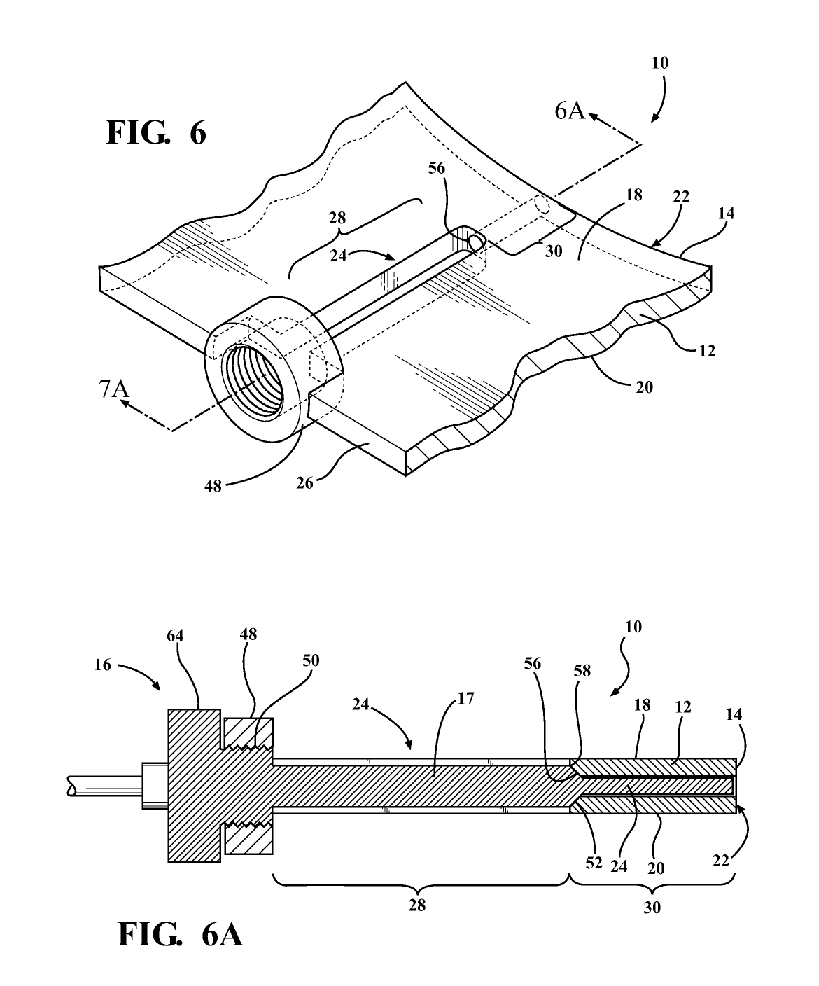

As shown in FIGS. 6 and 6A, a gasket assembly 10 constructed in accordance with another aspect of the invention has the pressure sensor assembly 16 at least partially releasably attached in sealed engagement with the gasket body 12. The pressure sensor assembly 16 includes a pressure sensor 17 that is configured to sense pressure within the through passage 14 and within the cylinder bore being sealed. To form a reliable seal between the gasket body 12 and the pressure sensor 17 in manufacture and to maintain a reliable seal between the gasket body 12 and the pressure sensor 17 during use, a coating of sealant 52 is chemically bonded to the pressure sensor 17 and then brought into gas/liquid-tight sealed engagement with the gasket body 12. Accordingly, the pressure sensor 17 is chemically bonded to the sealant 52 and thus, in service, when the pressure sensor assembly 16, including at least the pressure sensor 17, is removed from the gasket body 12 and replaced, the sealant 52 peels cleanly from the gasket body 12 to provide a clean, sealant free surface on the gasket body 12 for a new pressure sensor having a fresh sealant to be bonded thereto.

The gasket body 12 can be provided as described above, having passages 24 formed with a through slot portion 28 extending from the outer periphery 26 radially inwardly toward respective through passage 14. The through slot portion 28 can be milled or otherwise machined through the sealing surfaces 18, 20. In addition, the passages 24 are formed with an enclosed tubular portion 30, also referred to as a drilled portion, extending from the through slot portion 28 radially inwardly to the respective inner periphery 22. The drilled portion 30 can be sized for a close fit, such as line-to-line, with a portion of the pressure sensor 17, or it can be enlarged for receipt of an adaptor sleeve, seal, heat shield, or other type of fitting. To facilitate forming the gas/fluid tight seal between the pressure sensor 17 and the gasket body 12, an annular gasket body seal seat 56 is formed at the entrance to the tubular portion 30, wherein the annular seal seat 56 is shown as having a female conical surface configured for operably sealed engagement with an annular sensor seal seat 58. The sensor seal seat 58 is configured to mate with the gasket seal seat 56, and thus, in the embodiment shown, the sensor seal seat 58 has an outer male conical surface having the same or substantially the same angle of inclination as the gasket seal seat 56.

To facilitate attaching the pressure sensor assembly 16 to the gasket body 12, a nut 48 can be fixed, such as via welding, to the outer periphery 26, shown as being partially recessed in the outer periphery 26. The nut 48 is configured in axial alignment with the passage 24 and is sized for threaded attachment to a male threaded portion 50 of the pressure sensor 17 and/or an outer housing of the pressure sensor assembly 16.

The pressure sensor 17 is shown as having a reduced diameter tip portion 60 sized for close receipt in the drilled portion 30 and an enlarged diameter portion 62 sized for receipt in the through slot portion 28, with the gasket seal seat 56 tapering therebetween. In the embodiment shown, the enlarged diameter portion has the same, or a slightly reduced diameter than the thickness of the gasket body 12, thereby allowing flush abutment against one or more functional layers (not shown) or adjacent engine component, i.e. cylinder head and engine block (not shown).

The sealant 52 is chemically bonded to the sensor sealing seat 58 and cured prior to installation of the sensor assembly 16 to the gasket body 12. In one example, the sealant 52, such as FTP30, by way of example, was cured at about 400 degrees Fahrenheit for about 10 minutes. As such, after curing the sealant 52 and then attaching the pressure sensor assembly 16 to the gasket body 12, the compliant, cured sealant 52 is compressed against the gasket sealing seat 56. As shown in FIG. 6A, the pressure sensor assembly 16 can be provided with a tool receiving portion 64, such as a hex-shaped outer surface of a housing, for example, thereby allowing a tool to readily grip and tighten the pressure sensor assembly 16 in releasably fixed relation to the gasket body 12. Upon tightening the pressure sensor assembly 16 to a predetermined torque range, the tool receiving portion 64 remains axially spaced from the nut 48, thereby assuring the sealant 56 is compressed between the seal seats 56, 58 to form the gas/fluid tight seal. The sealant 56 is compliant, and thus, during compression, fills any voids or scratches existing in the surface finish of the gasket sealing seat 56. With the sealant 52 being chemically bonded to the sensor sealing seat 58, upon removal of the pressure sensor 17 from the gasket body 12, the sealant 52 peels cleanly from the gasket sealing seat 56, thereby leaving a clean metal surface on the gasket sealing seat 56, such that the gasket sealing seat 56 is free of the material from the sealant 52. Thus, upon fastening a replacement pressure sensor assembly 16 to the gasket body 12, a fresh gas/fluid-tight seal can be readily formed by a new sealant 52 chemically bonded to the replacement pressure sensor 17. Further, with the coating of sealant 52 being chemically bonded to the sensor sealing seat 58, the sealant 52 is assured of remaining properly positioned during assembly, thereby forming a reliable gas/fluid seal upon being reliably compressed between the sealing seats 56, 58.

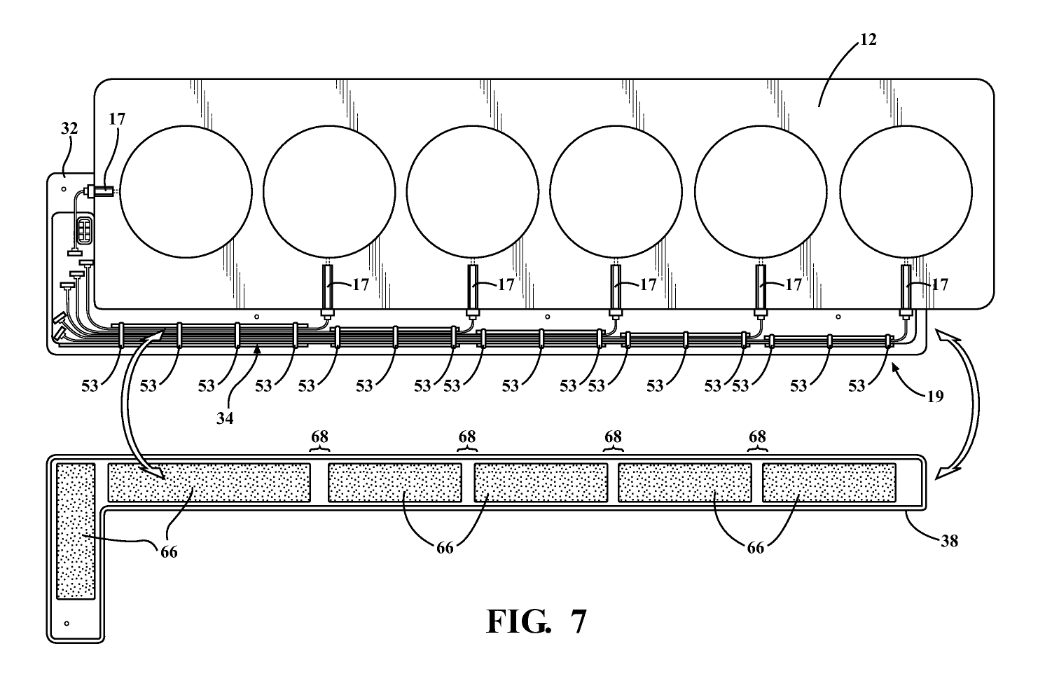

In FIG. 7, another gasket assembly constructed in accordance with the invention is shown. The assembly 10 is configured similarly to the assembly 10 of FIG. 1, however the peripheral shelf 32 is constructed separately from the sealing portion of the gasket body 12 that is clamped between the engine block and the cylinder head. The peripheral shelf 32 is configured generally the same as discussed above with regard to FIG. 1, however, it can be molded or otherwise formed of a suitable plastic material, for example, and fastened or otherwise fixed to the gasket body 12. For example, the peripheral shelf 32 can be molded directly to the gasket body 12, welded to the gasket body (metal peripheral shelf to metal gasket body, or plastic peripheral shelf to metal gasket body), or other fastened with suitable fasteners. As with the previous embodiment, the assembly 10 includes a cover 38 having a suitably shaped configuration to overlie the peripheral shelf 32 and to protect the electronic members 19 carried by the peripheral shelf 32. Further, the cover 38 is shown as having dampeners 50 in the form of an elastomeric padding attached to the underside of the cover 38, thereby being brought into cushioning contact with the electronic members 19 upon assembly. In addition, the dampeners 50 act to reduce vibration and movement of the electronic members 19, thereby reducing the source of any potential noise and frictional wear. The dampeners 50 can be spaced from one another via gaps 68 to accommodate the sensors 17, thereby allowing for their removal during service, if required. In addition, the wires 34 can be tied or fastened to the peripheral shelf 32 via straps, bands, or other suitable fasteners 53, thereby further ensuring the wires 34 remain in their intended fixed positions, free from movement that could otherwise be caused by vibration.

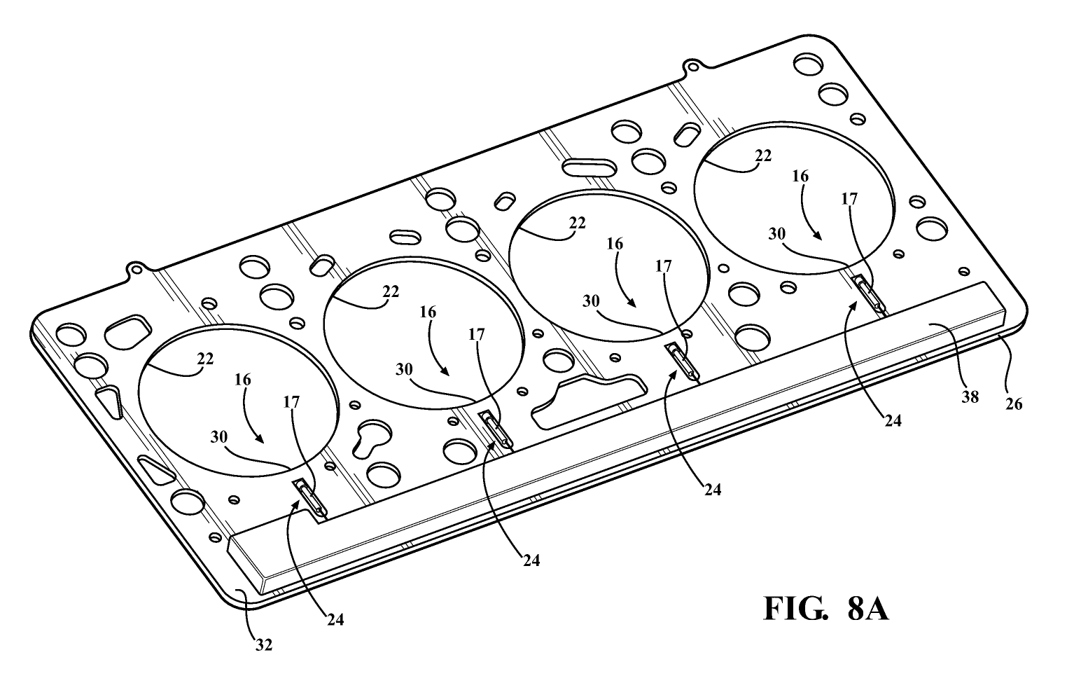

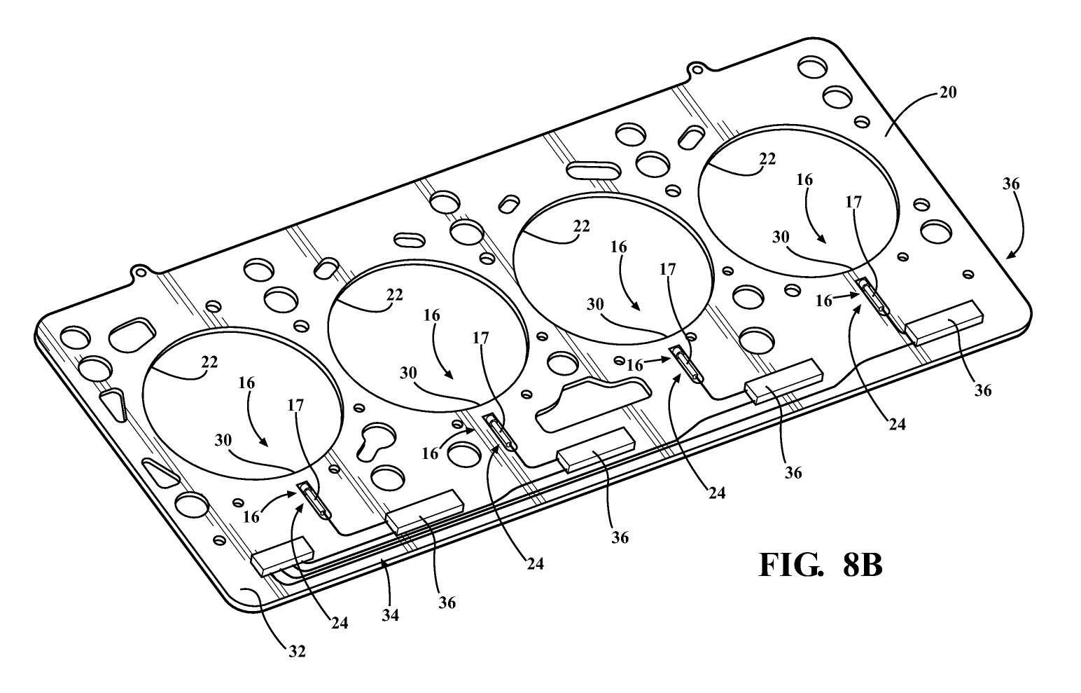

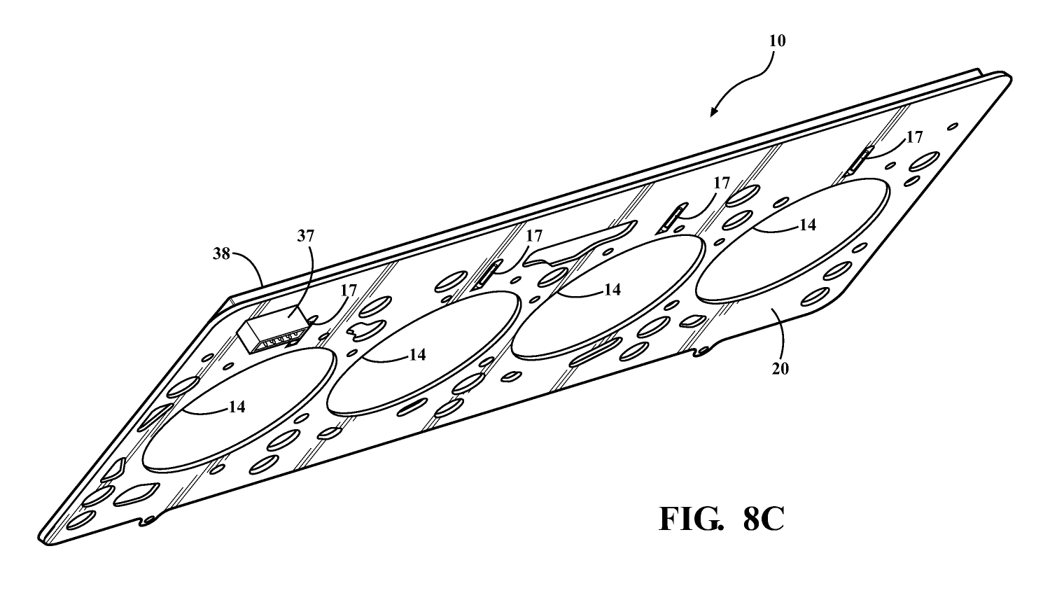

In FIGS. 8A and 8B, a gasket body assembly 10 constructed in accordance with another aspect of the invention is shown having a permanent pressure sensor assembly 16 fixed thereto. In this embodiment, a passage 24 extends from the inner periphery 22 of each through openings 14 in the gasket body 12 radially outwardly, however, the passage 24 does not exit the outer periphery 26 of the gasket body 12. Rather, each pressure sensor 17 is received in an enclosed tubular portion 30 adjacent the inner periphery 22, while the wires 34 connected to the pressure sensor 17 are routed radially outwardly along a shelf 32 for electrical connection to a PCB or plurality of PCB's 36 configured in electrical communication with a pin connector 37 (FIG. 8C).

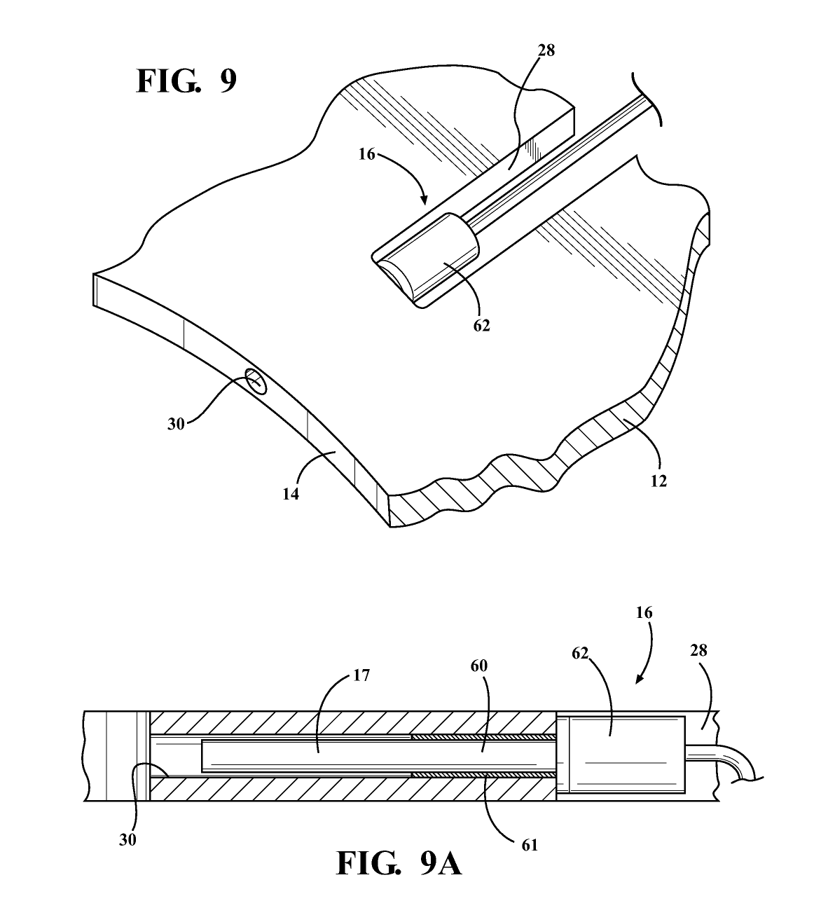

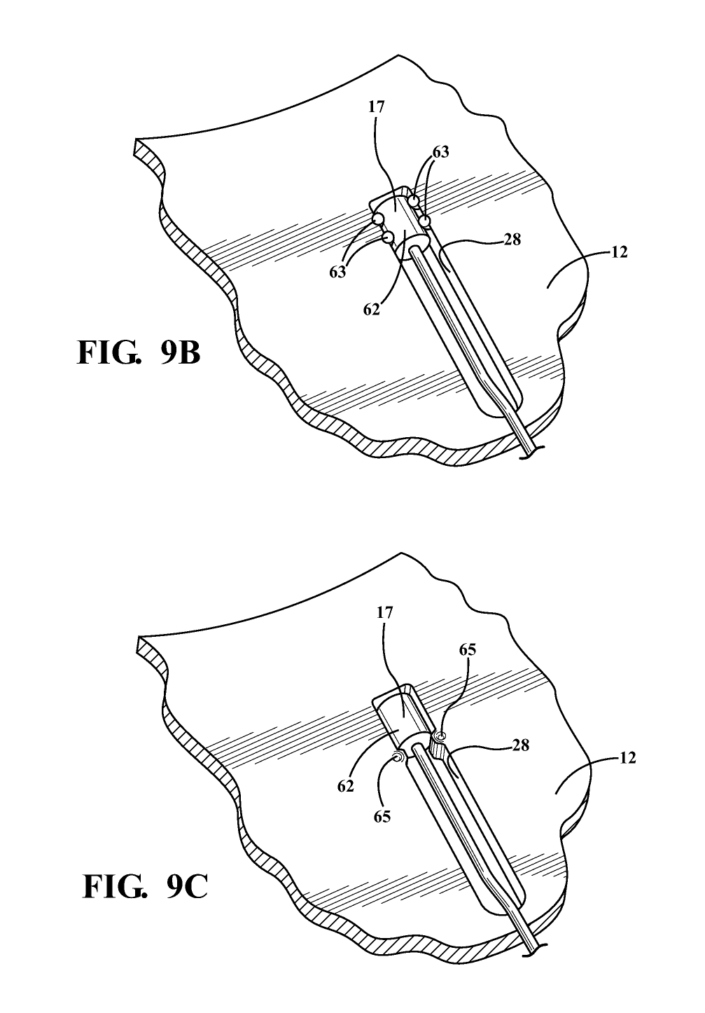

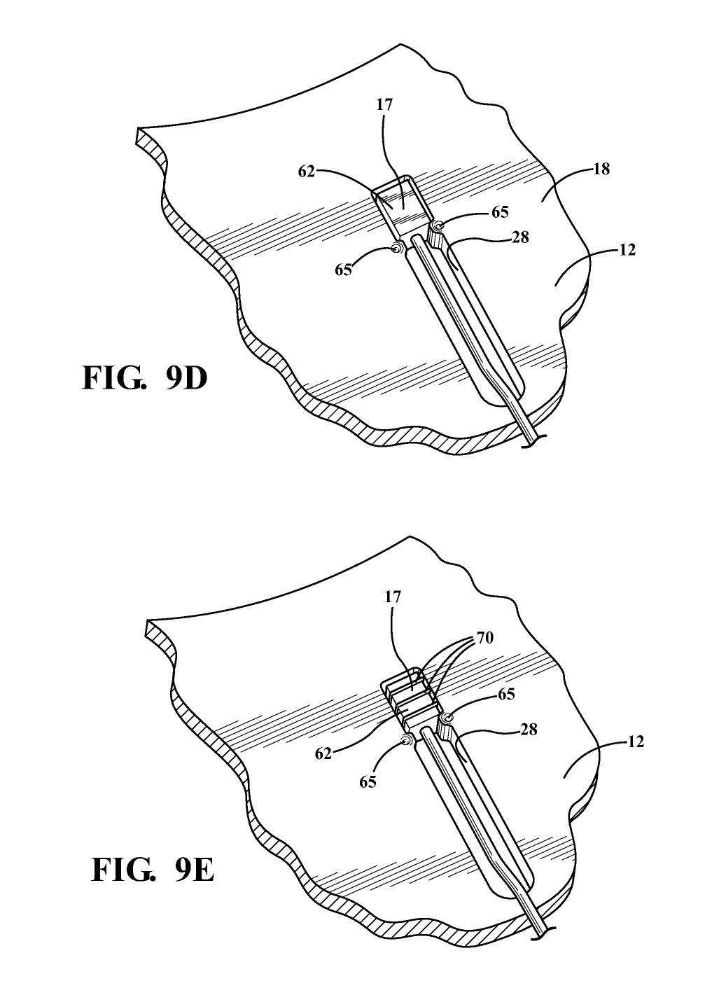

As shown in FIG. 9, a portion of a gasket assembly 10 constructed in accordance with another aspect of the invention is shown, wherein the pressure sensor 17 is permanently fixed to the gasket body 12. As shown in FIGS. 9A-9E, a variety of mechanisms can be used to fix the pressure sensor 17 to the gasket body 12 in the through slot portion 28. For example, the reduced diameter portion 60 can be soldered within at least a portion of the tubular portion 30 by wicking solder 61 therein and/or it can be soldered to the gasket body at least partially within the through slot portion 28 (FIG. 9A); the enlarged diameter portion 62 of the pressure sensor 17 can be tack welded via weld joints 63 to the gasket body 12 within the through slot portion 28 (FIG. 9B); the enlarged diameter portion 62 of the pressure sensor 17 can be swaged in place by swaging the material 65 of the gasket body 12 laterally inwardly into the through slot portion 28 to axially confront an end of the enlarged diameter portion 62 (FIG. 9C); the enlarged diameter portion can be oversized to extend outwardly beyond the sealing surfaces 18, 20 and then the oversized portion 62 can be plastically deformed along with swaging the material 65 of the gasket body 12 laterally inwardly into locked engagement with the pressure sensor 17 (FIG. 9D); and similarly to FIG. 9D, both the enlarged diameter portion 62 and the material 65 of the gasket body 12 can be plastically deformed into locked engagement with one another, wherein the enlarged diameter portion 62 has polymeric or metal annular rings 70 extending thereabout to facilitate gripping the gasket body 12 (FIG. 9E).

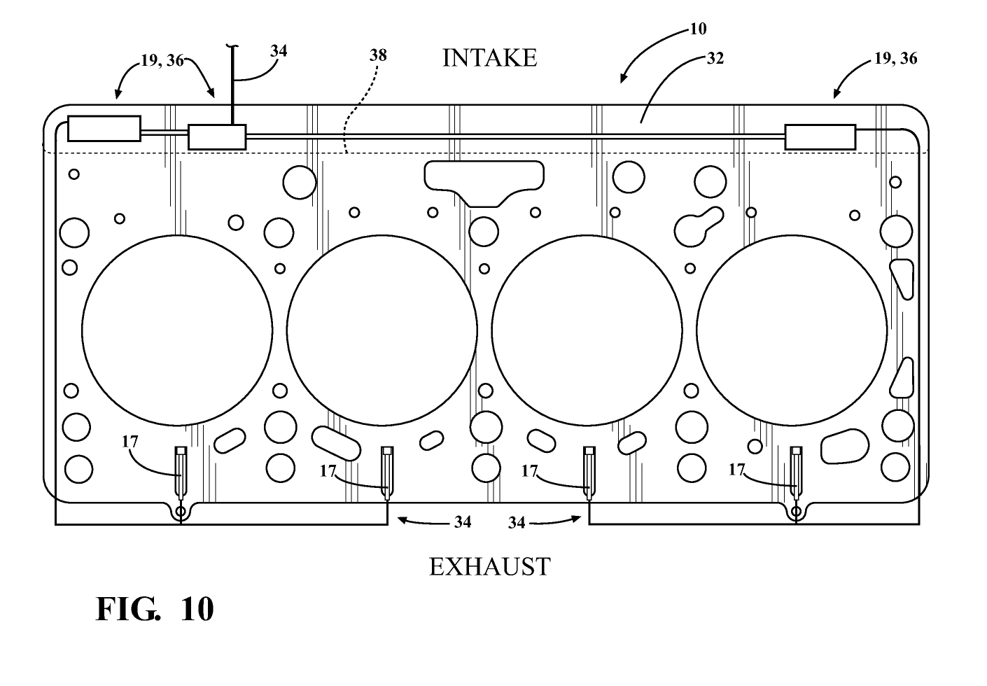

In FIG. 10, a schematic view is shown illustrating a gasket assembly 10 constructed in accordance with another aspect of the invention wherein the pressure sensors 17 are assembled on an exhaust side of the gasket body 12 and the electronic members 19, 36 are assembled on an intake side of the gasket body 12. Further, the electronic members 19, 36 are replaceable, while the sensors 17 are permanent.

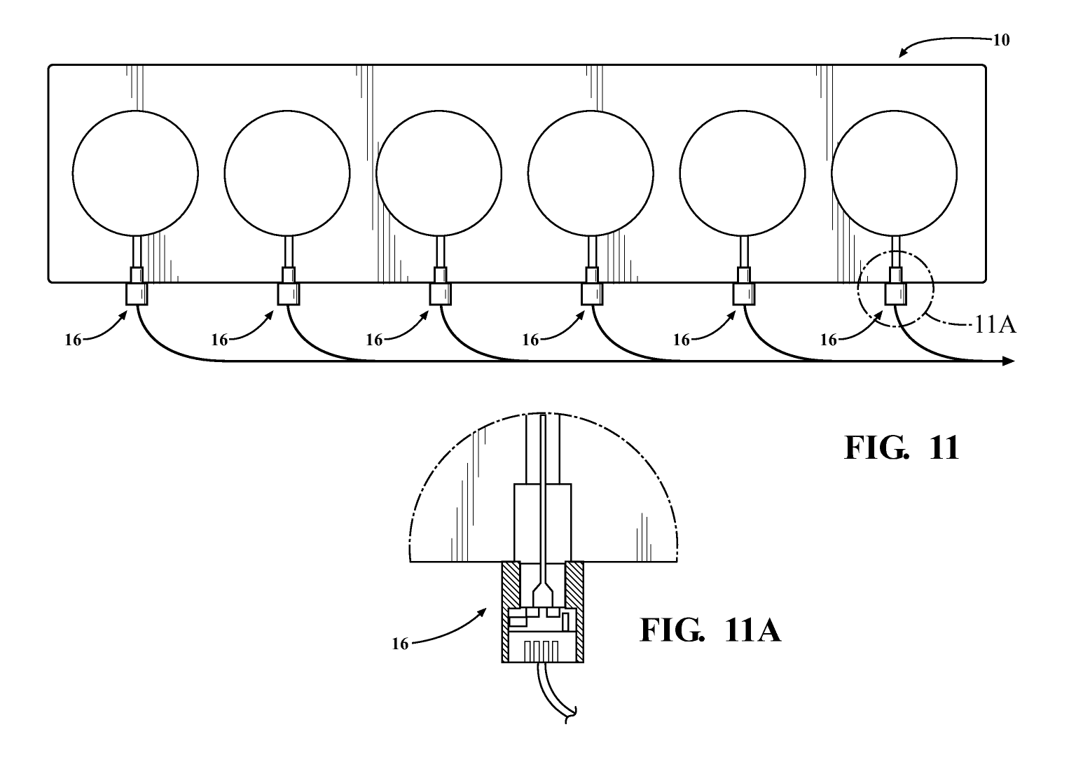

In FIG. 11 a gasket assembly 10 is shown wherein the pressure sensor assemblies 16 having integrated electronics housed within a housing of the pressure sensors 17. Accordingly, the individual pressure sensor 17 and its associated electronics can be readily replaced separately from other pressure sensors 17 of the gasket assembly 10.

Obviously, many modifications and variations of the present invention are possible in light of the above teachings. It is, therefore, to be understood that within the scope of the appended claims, the invention may be practiced otherwise than as specifically described.

What is claimed is:

1. A cylinder head compression sensor gasket assembly, comprising:
a gasket body having a sealing portion configured to be clamped between an engine block and a cylinder head, said sealing portion having a plurality of through openings extending therethrough, each of said through openings being configured to register with separate cylinder bore in the engine block wherein said sealing portion establishes a gas-tight seal about said through passages;
a plurality of pressure sensor assemblies attached in sealed engagement with said gasket body, at least one of said pressure sensor assemblies being configured to sense pressure within a separate one of said through openings; and
an electrical connector supported on said gasket body radially outwardly from said sealing portion, said electrical connector being configured in electrical communication with each of said pressure sensor assemblies.

2. The cylinder head compression sensor gasket assembly of claim 1 wherein said pressure sensor assemblies are releasably attached to said gasket body.

3. The cylinder head compression sensor gasket assembly of claim 2 wherein said gasket body has female threaded portions and said pressure sensor assemblies have a male threaded portion, said female threaded portions and male threaded portion being configured for threaded attachment to one another.

4. The cylinder head compression sensor gasket assembly of claim 3 wherein said gasket body has female conical seats and said pressure sensor assemblies have male conical seats, said female conical seats and said male conical seats being configured for sealed abutment with one another upon threadingly attaching respective ones of said female and male threaded portions to one another.

5. The cylinder head compression sensor gasket assembly of claim 4 further comprising a sealant chemically bonded to at least one of said female conical seats and said male conical seats.

6. The cylinder head compression sensor gasket assembly of claim 5 wherein said sealant is cured.

7. The cylinder head compression sensor gasket assembly of claim 1 wherein said pressure sensor assemblies have sensor tips recessed radially outwardly from said through openings and further comprising heat shields disposed between said sensor tips and said through openings.

8. The cylinder head compression sensor gasket assembly of claim 7 further comprising a mesh of material between said heat shields and said sensor tips.

9. The cylinder head compression sensor gasket assembly of claim 7 wherein said heat shields are annular.

10. The cylinder head compression sensor gasket assembly of claim 1 wherein said gasket body has opposite planar sealing surfaces and enclosed tubular portions extending between said seal surfaces through to said through openings, said pressure sensor assemblies extending through said tubular portions.

11. The cylinder head compression sensor gasket assembly of claim 10 wherein said pressure sensor assemblies are fixed in said tubular portions by solder extending in direct contact with said pressure sensor assemblies and said gasket body.

12. The cylinder head compression sensor gasket assembly of claim 10 wherein said gasket body has through slots extending through said sealing surfaces radially outwardly from said tubular portions.

13. The cylinder head compression sensor gasket assembly of claim 12 wherein said pressure sensor assemblies are fixed to said gasket body within said through slots.

14. The cylinder head compression sensor gasket assembly of claim 13 wherein weld joints within said through slots bond said pressure sensor assemblies to said gasket body.

15. The cylinder head compression sensor gasket assembly of claim 13 wherein material of said gasket body is upset within said through slots to fix said pressure sensor assemblies to said gasket body.

16. The cylinder head compression sensor gasket assembly of claim 15 wherein material of said pressure sensor assemblies is upset within said through slots to fix said pressure sensors to said gasket body.

17. The cylinder head compression sensor gasket assembly of claim 12 further comprising annular members disposed within said through slots about said pressure sensor assemblies, said annular members being compressed between said pressure sensor assemblies and said gasket body.

18. The cylinder head compression sensor gasket assembly of claim 2 wherein said pressure sensor assemblies are configured to be removable from said gasket body while said gasket body remains sealed between the cylinder head and an engine block.

19. The cylinder head compression sensor gasket assembly of claim 1 wherein each of said pressure sensor assemblies is separately detachable from electrical communication with said electrical connector.

20. The cylinder head compression sensor gasket assembly of claim 1 wherein said gasket body has an exhaust side and an opposite intake side, said pressure sensor assemblies being attached to said gasket body on said exhaust side and said electrical connector being attached to said gasket body on said intake side.

21. A method of constructing a cylinder head compression sensor gasket assembly, comprising:
forming a gasket body having a opposite sealing portions configured to be clamped between an engine block and a cylinder head and a plurality of through openings configured to register with separate cylinder bores in the engine block;
attaching a pressure sensor assembly adjacent each through opening in sealed engagement with the gasket body; and
fixing an electrical connector to the gasket body with the electrical connector extending radially outwardly from the sealing portion and configuring the electrical connector in electrical communication with each of the pressure sensor assemblies.

22. The method of claim 21 further including releasably attaching the pressure sensor assemblies to the gasket body.

23. The method of claim 22 further including threading the pressure sensor assemblies to the gasket body and bringing conical seats on the pressure sensor assemblies into sealed relation with conical seats in the gasket body.

24. The method of claim 23 further including bonding a sealant between the conical seats of the pressure sensor assemblies and the gasket body.

25. The method of claim 24 further including curing the sealant on one of the pressure sensor assembly conical seats or the gasket body conical seats prior to bringing the conical seats into sealed relation with one another.

26. The method of claim 21 further including recessing sensor tips of the pressure sensor assemblies radially outwardly from the through openings and disposing heat shields disposed between said sensor tips and said through openings.

27. The method of claim 26 further including disposing a mesh of material between the heat shields and the sensor tips.

30. The method of claim 21 further including forming enclosed tubular portions extending between opposite seal surfaces of the gasket body with the enclosed tubular portion extending to the through openings and soldering the pressure sensor assemblies in the tubular portions.

32. The method of claim 21 further including forming enclosed tubular portions extending between opposite seal surfaces of the gasket body with the enclosed tubular portion extending to the through openings and forming through slots extending through the sealing surfaces and radially outwardly from the tubular portions and fixing the pressure sensor assemblies to the gasket body within the through slots.

33. The method of claim 32 further including performing the fixing with weld joints.

34. The method of claim 32 further including performing the fixing by upsetting material of the gasket body within the through slots.

35. The method of claim 34 further performing the fixing by upsetting material of the pressure sensor assembly within the through slots.

36. A method of servicing a pressure sensor that is sandwiched between the cylinder head and the cylinder block of an internal combustion engine, comprising:
while leaving the cylinder head attached to the engine block, removing the pressure sensor from between the cylinder head and the cylinder block and inserting a replacement pressure sensor.
